(19) United States
(12) Patent Application Publication
(10) Pub. No.: US 2023/0243910 A1
(43) Pub. Date: Aug. 3, 2023

(54) METHOD AND DEVICE FOR RAPIDLY ACQUIRING AND RECONSTRUCTING A SEQUENCE OF MAGNETIC RESONANCE IMAGES COVERING A VOLUME

(71) Applicant: Max-Planck-Gesellschaft zur Foerderung der Wissenschaften e. V., Muenchen (DE)

(72) Inventors: Jens FRAHM, Goettingen (DE); Dirk VOIT, Goettingen (DE)

(21) Appl. No.: 17/927,505

(22) PCT Filed: May 26, 2020
(86) PCT No.: PCT/EP2020/064580

§ 371 Date: Nov. 23, 2022

(51) Int. Cl. G01R 33/56; G06T 5/20; G06T 11/00; G01R 33/48

(52) U.S. Cl. CPC G01R 33/5608; G06T 5/20; G06T 11/008; G01R 33/4824; G06T 2207/20032

(57) ABSTRACT

A method for creating, in particular acquiring and reconstructing, a sequence of magnetic resonance (MR) images of an object (1), said sequence of MR images representing a series of cross-sectional slices (2) of the object (1), comprises (a) providing a series of sets of image raw data including an image content of the MR images to be reconstructed, said image raw data being collected with at least one radiofrequency receiver coil of a magnetic resonance imaging (MRI) device, wherein each set of image raw data includes a plurality of data samples being generated in an imaging plane with a gradient-echo sequence that spatially encodes an MRI signal received with the at least one radiofrequency receiver coil using a non-Cartesian k-space trajectory, each set of image raw data comprises a set of homogeneously distributed lines in k-space with equivalent spatial frequency content, the lines of each set of image raw data cross the center of k-space and cover a continuous range of spatial frequencies, the positions of the lines of each set of image raw data differ in successive sets of image raw data, and the number of lines of each set of image raw data is selected such that each set of image raw data is undersampled below a sampling rate limit defined by the Nyquist-Shannon sampling theorem, and (b) subjecting the sets of image raw data to a regularized nonlinear inverse reconstruction process to provide the sequence of MR images, wherein each of the MR images is created by a simultaneous estimation of a sensitivity of the at least one receiver coil and the image content and in dependency on a difference between a current estimation of the sensitivity of the at least one receiver coil and the image content and a preceding estimation of the sensitivity of the at least one receiver coil and the image content, wherein said cross-sectional slices (2) of the object (1) are contiguous cross-sectional slices (2) with a predetermined slice thickness, each set of said image raw data represents one of said contiguous cross-sectional slices (2), and the position of each cross-sectional slice is shifted by a slice shift A perpendicular to the imaging plane in order to cover a volume of the object (1).

### FIELD OF THE INVENTION

The present invention relates to a method for creating, in particular for acquiring and reconstructing, a sequence of magnetic resonance (MR) images covering a volume. Furthermore, the invention relates to a magnetic resonance imaging (MRI) device configured for implementing the method. Applications of the invention are available in the field of MR imaging, in particular medical MR imaging (e.g., imaging of inner organs) or non-medical investigations in natural sciences (e. g., investigations of a workpiece).

### BACKGROUND OF THE INVENTION

In the present specification, reference is made to the following prior art illustrating the technical background of the invention, in particular relating to acquisition and reconstruction of MR images:
[1] J. Frahm et al. in “J. Comput. Assist. Tomogr.” 10:363-368, 1986;
[2] U.S. Pat. No. 4,707,658 A;
[3] M. Weiger et al. in “MAGMA” 14:10-19, 2002;
[4] Y.-C. Kim et al. in “Magn Reson Med” 61:1434-1440, 2009;
[5] G. H. Glover in “Neurosurg. Clin. N. Am.” 22:133-139, 2011;
[6] US 2011/0234222 A1; and
[7] M. Decker et al. in “NMR Biomed.” 23:986-994, 2010.

Since the conception of magnetic resonance imaging (MRI) in 1973, a general need relates to a method for rapid scanning of a volume of an object under investigation that, for example in medical imaging, achieves comprehensive imaging of an entire human organ within a short period of time and with robustness against motion. Potential clinical applications span a wide field ranging from studies of less cooperative patients, children and infants (e.g., to reduce or completely avoid sedation or anesthesia) to studies in the presence of unavoidable movements such as in abdominal or fetal imaging and perfusion studies after contrast injection which require repetitive imaging of an entire organ (e.g., mamma, liver, prostate) at adequate temporal resolution.

A first and in many cases advantageous solution to volume coverage is 3D MRI which became possible by the 1985 FLASH invention offering measuring times of a few minutes (e.g., see [1], [2]). Almost two decades later the advent of parallel MRI, which exploits mild data undersampling in conjunction with multiple receive coils (now a standard in all commercial MRI systems), resulted in a further acceleration, typically by a factor of two per dimension (e.g., see [3]). More recently, highly specialized applications achieved 3D MRI measuring times of several seconds (e.g., see [4]).

However, all 3D MRI techniques are inherently sensitive to motion, which is due to the fact that the temporal footprint for image reconstruction matches the total acquisition time, or in other words, the entire 3D MRI dataset contributes to each retrospectively reconstructed image plane. This property manifests a general disadvantage as object movements during a 3D acquisition dis-turb the reconstruction of the entire 3D volume.

An alternative solution to cover a volume is by multi-slice acquisitions of cross-sectional images. For example, when using the FLASH technique with a measuring time of one second per cross-sectional image, the technique leads to a measuring time of 50 seconds if a 150 mm thick volume is sequentially scanned by 50 neighbouring sections of 3 mm thickness. However, individual images may still suffer from movements faster than the individual acquisition time (e.g., cardiac pulsations) and the overall measuring time is still too slow for many clinical applications.

An even faster multi-slice acquisition is possible when using the echo-planar imaging (EPI) technique for cross-sectional imaging. Such implementations are commonly employed for functional MRI studies of the human brain (e.g., see [5]). Whole-brain coverage may be achieved within 2 to 3 seconds for a set of neighbouring sections which are sequentially acquired to cover the entire brain with blood oxygenation level dependent (BOLD) contrast. However, a most relevant disadvantage of EPI-based techniques is the sensitivity to magnetic field inhomogeneity. As a multi-echo gradient-echo sequence which relies on the acquisition of many gradient echoes with neces-sarily increasing echo times—typically applied as a single-shot technique with all gradient echoes following a single radiofrequency excitation—EPI suffers from an inherent and strong sensitivity to magnetic field inhomogeneity which in the human body is unavoidable because biologic tissues differ in their magnetic susceptibilities. While this inhomogeneity sensitivity is a desired feature for BOLD MRI, which depends on activity-induced changes of the local concentration of paramag-netic deoxyhemoglobin, unwanted consequences in EPI images are geometric distortions, artificial positive or negative signal alterations or even a complete signal void in affected regions. These problems are, for example, effective in lower and frontal parts of the brain (i.e., close to air-filled cavities or to dental repair) and are frequent throughout the body such as in MRI of the prostate (i.e., close to the air-filled rectum).

An extremely accelerated method for acquiring and reconstructing a sequence of dynamic MR images has been proposed in [6]. The use of a gradient-echo MRI sequence with pronounced undersampling, non-Cartesian trajectories for spatial encoding, and image reconstruction by regularized nonlinear inversion results in acquisition times in the range of tens of milliseconds. Thus, depending on the dynamic process to be studied, temporal changes of the object under investigation can be monitored in real-time. However, the technique of [6] is mainly directed to collect images of a single slice of the object, so that coverage of a volume of an object under investigation is not obtained. Although collecting images of different slices of the object is considered in [6] as well, this is limited to a few slices, like e. g. less than 5 slices. Furthermore, the corresponding applications are realized as interleaved multi-slice data acquisitions, so that the technique of [6] sacrifices temporal resolution and increases the sensitivity to motion.

### OBJECTIVE OF THE INVENTION

The objective of the invention is to provide an improved method for creating, in particular acquiring image raw data and reconstructing, a sequence of cross-sectional MR images covering a volume of an object under investigation, while avoiding disadvantages of the conventional techniques and/or allowing new applications of MR imaging. In particular, the objective of the invention is to provide an improved method for creating a sequence of cross-sectional MR images for gap-free volume coverage with increased acquisition speed, reduced sensitivity to motion, and reduced sensitivity to magnetic field inhomogeneity. For medical imaging applications, the improved MRI method is to be capable of covering a volume of a human body without gaps, thus allowing for comprehensive imaging of entire human organs or organ systems. Furthermore, the objective of the invention is to provide an improved MRI device, in particular being adapted for conducting the method for rapidly acquiring and reconstructing a sequence of MR images covering a volume.

### SUMMARY OF THE INVENTION

The above objectives are solved by an MR image creating method and/or an MRI device comprising the features of the independent claims. Advantageous embodiments of the invention are defined in the dependent claims.

According to a first general aspect of the invention, the above objective is solved by a method for creating, in particular acquiring image raw data and reconstructing, a sequence of MR images of an object under investigation, wherein the sequence of MR images represents a series of contiguous cross-sectional slices of the object.

The inventive method comprises a step of providing a series of sets of image raw data including an image content of the MR images to be reconstructed. The image raw data are data collected with the use of at least one radiofrequency receiver coil of a magnetic resonance imaging device. Each set of image raw data includes a plurality of data samples being generated in an imaging plane with a gradient-echo sequence that spatially encodes an MRI signal received with the at least one radiofrequency receiver coil using a non-Cartesian k-space trajectory. Furthermore, each set of image raw data comprises a set of homogeneously distributed lines in k-space with equivalent spatial frequency content, wherein the lines of each set of image raw data cross the center of k-space and cover a continuous range of spatial frequencies and the positions of the lines of each set of image raw data differ in successive sets of image raw data. The number of lines of each set of image raw data is selected such that each set of image raw data is undersampled below a sampling rate limit defined by the Nyquist—Shannon sampling theorem (also known as Whittaker-Ko-telnikow-Shannon sampling theorem).

Furthermore, the inventive method comprises a step of subjecting the sets of image raw data to a regularized nonlinear inverse reconstruction process to provide the sequence of MR images. Each of the MR images is created by a simultaneous estimation of a sensitivity of the at least one receiver coil and the image content and in dependency on a difference between a current estimation of the sensitivity of the at least one receiver coil and the image content and a preceding estimation of the sensitivity of the at least one receiver coil and the image content.

According to the invention, the cross-sectional slices of the object are contiguous cross-sectional slices with a predetermined slice thickness. Each set of said image raw data represents a different one of said contiguous cross-sectional slices, i. e. each set of image raw data in particular comprises image information of one of the cross-sectional slices. The position of each cross-sectional slice is shifted by a slice shift in a direction perpendicular to the imaging plane in order to cover a volume of the object under investigation. The slice shift is a distance between directly neighbouring parallel cross-sectional slices in the direction perpendicular to the imaging plane and equal to a certain percentage (above 0% and up to 100%) of the slice thickness of the cross-sectional slices. The spatial orientation of the imaging plane, e. g. relative to the z direction of the main magnetic field of the MRI device, can be selected in dependency on an imaging task, e. g. in dependency on the anatomical orientation of an organ to be imaged in a human body. The spatial orientation of the imaging plane can be set by directions of the spatially encoding magnetic field gradients in the MRI device.

Advantageously, the invention provides a method allowing a rapid acquisition of a sequence of cross-sectional gradient-echo MR images of an object under investigation with a certain degree of undersampling, preferably with radial encoding, which cover a volume of the object by sequentially advancing the position of each cross-sectional slice (i.e., each imaging plane) by the slice shift. Reconstruction of the series of images and their corresponding coil sensitivity maps is accomplished by the regularized nonlinear inverse reconstruction process which jointly estimates each image and its corresponding (associated) coil sensitivity maps while exploiting the spatial similarity of a currently reconstructed image to the preceding image and its corresponding (associated) coil sensitivities.

The nonlinear inverse reconstruction process is an iterative process which in each iterative step solves a regularized linearization of a nonlinear MRI signal equation which maps the unknown spin density to be measured and its coil sensitivities to the data acquired from the at least one receiver coil. The inventors have found that the nonlinear inverse reconstruction process employing the similarity of temporally successive images of a given image plane as described in [6] can be used for reconstructing spatially successive images of the contiguous cross-sectional slices, i. e. images of different imaging planes. This is a surprising result as it was not expected before the invention that adjacent cross-sectional slices have sufficient similarity for successfully applying the nonlinear inverse reconstruction process, even with objects having step-wise changes of the spin density therein.

Contrary to [6], the inventive method primarily does not provide a sequence of temporally changing (dynamic) MR images, but a sequence of spatially distributed (static) MR images of the object, resulting in new and extended applications of MR imaging in particular with regard to volume coverage of the object, which can be obtained with increased acquisition speed. Due to the increased acquisition speed, reduced sensitivity to motion is obtained.

A particular advantage of the invention relates to the fact that—because of the short measuring times of the individual undersampled gradient-echo images of each cross-sectional slice—motion-induced artefacts are effectively reduced or even completely avoided. In particular for medical imaging it is of further advantage that also the resulting measuring time for covering an entire volume, e. g. of an inner organ or a complete body, is typically only a few seconds.

According to a second general aspect of the invention, the above objective is solved by an MRI device being configured for creating a sequence of MR images of an object under investigation and comprising an MRI scanner and a control device. According to the invention, the control device is adapted for controlling the MRI scanner for collecting the series of sets of image raw data and reconstructing the sequence of MR images with the method according to the first aspect of the invention or one of the embodiments thereof. The MRI scanner includes a main magnetic field device, at least one radiofrequency excitation coil, three magnetic field gradient coils and at least one radiofrequency receiver coil.

According to a preferred embodiment of the invention, the reconstruction method comprises a further step of combining the MR images for creating a three-dimensional image of the object, in particular the covered volume thereof. Combining the MR images comprises registering image information of the contiguous cross-sectional slices and optionally deleting redundant image information in case of overlapping cross-sectional slices. Advantageously, this embodiment of the invention further allows creating three-dimensional representations of the covered volume by spe-cially reconstructed imaging planes or projections along arbitrary orientations e. g. when subjecting the set of individual cross-sectional images to suitable software for 3D viewing. For example, in medical imaging, it is possible to generate maximum intensity projections of the combined data to obtain a magnetic resonance angiogram of vascular structures. Standardized image processing software for creating the three-dimensional image of the object is available on almost all commercial MRI systems.

According to a further preferred embodiment of the invention, the reconstruction process includes a filtering process suppressing image artifacts. Advantageously, filtering improves the image quality. With a particularly preferred variant, a median filter is applied to a small number of successive cross-sectional images and/or a spatial non-local means filter is applied to each image.

According to a further advantage of the invention, the slice shift of successive cross-sectional slices can be selected in dependency on requirements of a particular imaging task, in particular in dependency on a dimension of a volume to be imaged, an imaging speed and a spatial resolution to be obtained.

According to a first variant, the slice shift of successive cross-sectional slices in the perpendicular direction is equal to the slice thickness of the cross-sectional slices. With the term “equal to the slice thickness of the cross-sectional slices”, any slice shift of the precise amount of the slice thickness or nearly the slice thickness, e. g. in a range above 80% of the slice thickness, is covered. This embodiment has particular advantages in terms of imaging speed. In particular, high speed and the slice shift as large as nearly or equal to 100% of the slice thickness may be the preferred option for scanning a sequence of directly neighbouring cross-sectional images, preferably with spin density, T1 or T2* contrast with use of a single-echo or multi-echo FLASH (fast low-angle shot) sequence.

According to a second variant, the slice shift of successive cross-sectional slices in the perpendicular direction is selected in a range from 10% to 80% of the slice thickness of the cross-sectional slices. Advantageously, this embodiment provides an improved image quality and spatial resolution. In particular, if T2/T1-type contrast is a desired option, then preferably more radiofrequency excitations of the water protons are provided to establish a steady-state condition for transverse magnetizations, for example when using a FLASH sequence with refocused or fully balanced gradients.

As a further advantage of the invention, the method for reconstructing a sequence of MR images can be implemented with different gradient-echo sequences. A particular gradient-echo sequence, like e. g. a single-echo FLASH (fast low-angle shot) sequence, a multi-echo FLASH sequence, a FLASH sequence with refocusing read gradients, a FLASH sequence with reversely refocusing read gradients, or a FLASH sequence with fully balanced read and slice gradients can be selected in dependency on the imaging task.

As a further advantage of the invention, the image raw data can be selected with a high degree of undersampling, i.e. relative to a fully sampled reference which—e.g. for radial encoding with rotated straight lines and according to the sampling theorem—is given by π/2 times the number of data samples per line. The degree of undersampling can be at least a factor of 5, in particular at least a factor of 10, thus accelerating the data acquisition in the same manner as described for real-time MRI (e.g., see [7]). Accordingly, the number of lines of each set of image raw data can be reduced. In particular for medical imaging, it has been found that a number of lines equal or below 30, in particular equal or below 20 is sufficient for obtaining high quality MR image sequences.

Furthermore, the acquisition time of an individual cross-sectional image can be equal or below 100 ms, in particular equal or below 50 ms. Thus, the invention offers a solution to rapid scanning of a volume without sensitivity to motion. The practice of the invention yields high-quality images with acquisition times as short as 50 ms corresponding to a scanning speed of 20 images per second for moving through a volume at a predetermined slice shift.

According to a further preferred embodiment of the invention, the lines of each set of image raw data can be selected such that the lines of successive sets of image raw data are rotated relative to each other by a predetermined angular displacement. As an advantage, this rotation improves the effect of both the regularization and the filtering process within the image reconstruction.

According to further advantageous embodiments of the invention, the collection of each set of image raw data or a selectable number of sets of image raw data is interleaved with a radiofrequency and gradient module for spatial pre-saturation or for frequency-selective saturation. The radiofrequency and gradient modules comprise application of radiofrequency excitation pulses and magnetic field gradients on the object under investigation, which are selected for achieving specific contrasts depending on the imaging task. For example, a module for spatial saturation of at least a part of the volume of the object allows for the saturation (i.e., elimination) of signals from water protons flowing through the imaging plane of a cross-sectional image from either side. If applied to one side only, for example, the technique may distinguish between venous and arte-rial blood flow. In the alternative preferred embodiment, the interleaved module accomplishes a frequency-selective saturation (i.e., elimination) of proton resonance signals belonging to either water or lipid protons, thus providing water-only or fat-only series of images.

Although the invention is mainly directed to collecting static images of multiple cross-sectional slices, dynamic changes of the object can be imaged as well, in particular if a characteristic time constant of the dynamic changes is such that the object can be considered as sufficiently static during the steps of providing the series of sets of image raw data including an image content of the MR images to be reconstructed and subjecting the sets of image raw data to the regularized nonlinear inverse reconstruction process to provide the sequence of MR images. Thus, according to a further preferred embodiment of the invention, these steps can be repeated for monitoring dynamic changes of the object.

Advantageously, the inventive method for reconstructing a sequence of MR images can be conducted during and/or immediately after collecting the image raw data with the at least one radiofrequency receiver coil of the MRI device. In this case, providing the series of sets of image raw data comprises the steps of arranging the object in the MRI device including the at least one receiver coil, subjecting the object to the gradient-echo sequence, and collecting the series of sets of image raw data using the at least one receiver coil. Reconstructing the sequence of MR images can be conducted in real time, i. e. with a negligible delay relative to the image raw data collection. Alternatively, the reconstruction may require some time resulting in a certain delay in pre-senting the sequence of MR images.

According to an alternative embodiment, the inventive method for reconstructing the sequence of MR images can be conducted independently of collecting the image raw data with predetermined measurement conditions. In this case, the sets of image raw data can be received e. g. from a data storage, like in a data cloud storage, and/or a data transmission from a distant MRI device.

### BRIEF DESCRIPTION OF THE DRAWINGS

Further details and advantages of the invention are described with reference to the attached drawings, which show in

FIG. 1: a schematic illustration of a preferred embodiment of the MR image reconstruction method according to the invention;

FIG. 2: a schematic illustration of a preferred embodiment of an MRI device according to the invention;

FIG. 3: examples of T1-weighted MR images of the human abdomen with different slice shifts;

FIG. 4: examples of T2/T1-weighted MR images of the human brain with different slice shifts;

FIG. 5: examples of T2/T1-weighted MR images of the human brain selected from a volume coverage scan in 5.0 seconds;

FIG. 6: examples of T1-weighted MR images and a 3D reconstruction of the human carotid arteries selected from a volume coverage scan in 6.4 seconds;

FIG. 7: examples of T1-weighted MR images with interleaved fat saturation of the human liver selected from a volume coverage scan in 6.0 seconds; and

FIG. 8: examples of T2/T1-weighted MR images with interleaved fat saturation of the human prostate selected from a volume coverage scan in 6.0 seconds.

### DESCRIPTION OF THE PREFERRED EMBODIMENTS

Preferred embodiments of the invention are described in the following with particular reference to the data flow of the inventive reconstruction process, the basic components of an inventive MRI device and practical application examples.

The details of the design of gradient-echo sequences, k-space trajectories, raw data acquisition and the mathematical formulation and implementation of the regularized nonlinear inverse reconstruction are provided as disclosed in [6]. In particular, the regularized nonlinear inverse reconstruction process is implemented as disclosed in [6] for the reconstruction of time series of MR images of an object under investigation. Thus, [6] is incorporated to the present specification by reference in its entirety, in particular with regard to all details of data acquisition and image reconstruction of the sequence of cross-sectional gradient-echo MR images of the object under investigation. All procedural steps applied to time series of sets of raw data and sequences of MR images in [6] can be applied in the same manner to series of sets of raw data and sequences of MR images representing contiguous cross-sectional slices.

Further details of the MRI device, the construction of gradient echo sequences and their adapta-tion to a particular object to be imaged, the numerical implementation of the mathematical formulation using available software tools and optional further image processing steps are not described as far as they are known from conventional MRI techniques. Furthermore, exemplary reference is made in the following to parallel MR imaging wherein the image raw data comprise MRI signals received with a plurality of radiofrequency receiver coils. It is emphasized that the application of the invention is not restricted to parallel MR imaging, but rather possible even with the use of one single receiver coil.

Reconstruction Process and MRI Device

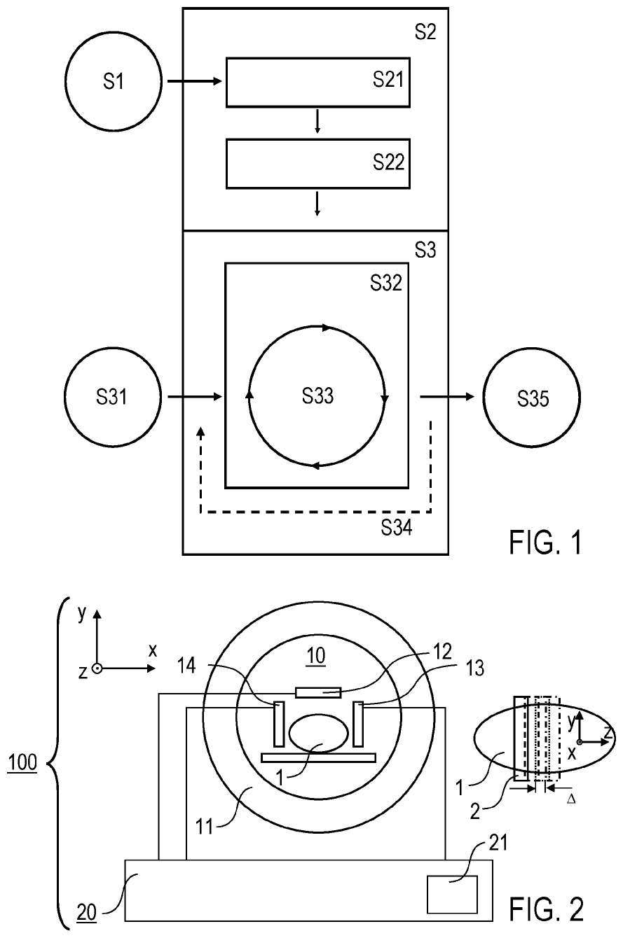

FIG. 1 summarizes a complete data flow of the inventive reconstruction process, as described in [6], comprising a first step S1 of collecting measured data, a second step S2 of preprocessing the measured data, and a third step S3 of iteratively reconstructing a sequence of MR images. FIG. 2 schematically shows an MRI device 100 with an MRI scanner 10 including a main magnetic field device 11, at least one radiofrequency excitation coil 12, three magnetic field gradient coils 13 and radiofrequency receiver coils 14. The object 1 to be investigated is accommodated in the MRI device 100. Furthermore, the MRI device 100 includes a control device 20 being adapted for controlling the MRI scanner 10 for collecting the series of sets of image raw data and reconstructing the sequence of MR images with the method according to FIG. 1. The control device 20 includes at least one GPU 21, which is preferably used for implementing the regularized nonlinear inversion.

With step S1, a series of sets of image raw data including an image content of the MR images to be reconstructed is collected with the use of the radiofrequency receiver coils 14 of the MRI device 100. The object 1, e. g. a tissue or organ of a patient, is subjected to a slice-selective radiofrequency excitation pulse and a gradient-echo sequence encoding the MRI signal received with the radiofrequency receiver coils 14. The gradient-echo sequence is constructed such that data samples are collected along non-Cartesian k-space trajectories. The slice shift is accomplished by changing the radiofrequency excitation pulse.

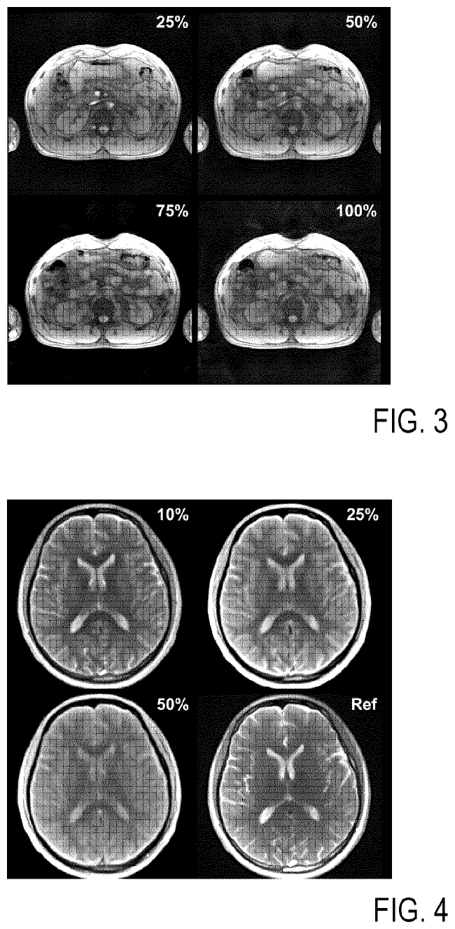

Examples of gradient-echo sequence are disclosed in FIGS. 3A, 3B and 4B of [6]. Deviating from [6], each set of the image raw data represents another one of contiguous cross-sectional slices 2 as shown in the schematic insert of FIG. 2.

With step S2, the image raw data are subjected to an optional whitening and array compression step S21 and to an interpolation step S22, wherein an interpolation of the non-Cartesian data onto a Cartesian grid is conducted. Steps 21 and 22 are implemented as disclosed in [6].

Finally, with step S3, the sequence of MR images of the object 1 is reconstructed by the regularized nonlinear inverse reconstruction process, which is described in [6]. Starting from an initial guess S31 for the MR image of a first cross-sectional slice and the coil sensitivities, each of the MR images is created by an iterative simultaneous estimation S32 of sensitivities of the receiver coils and the image content. Step S32 comprises the nonlinear inverse reconstruction using an iteratively regularized Gauss-Newton method including a convolution-based conjugate gradient algo-rithm S33. The number of iterations (Newton steps) is selected in dependency on the image quality requirements of a particular imaging task. Finally, the reconstructed series of MR images is output (S35). Further steps of conventional processing, storing, displaying, or recording of image data can follow.

### EXPERIMENTAL EXAMPLES

Experimental examples of the invention are described in the following with particular reference to applications in medical imaging. All examples refer to studies of healthy human subjects.

FIG. 3 shows T1-weighted images (50 ms acquisition time, 1.2×1.2 mm² in-plane resolution, 4.0 mm slice thickness) of the abdomen at the level of the kidneys which were obtained in separate volume coverage scans with a single-echo FLASH sequence and increasing slice shifts of 25% (1.0 mm), 50% (2.0 mm), 75% (3.0 mm), and 100% (4.0 mm), respectively, of the cross-sectional slice thickness. The comparison demonstrates the range of usable slice shifts for T1-weighted images which goes up to 100% of the slice thickness (i.e., directly neighbouring slice positions). The images also demonstrate robustness against peristaltic or breathing movements (i.e., the absence of motion artefacts). Slight differences are due to the fact that all 4 image series were obtained during free breathing which naturally affects the position of abdominal organs such as liver, pancreas and small bowel.

Complementary to the aforementioned example, FIG. 4 shows T2/T1-weighted images of the brain (50 ms acquisition time, 1.0×1.0 mm in-plane resolution, 6.0 mm slice thickness) which were obtained in separate volume coverage scans with a FLASH sequence with refocused read gradients and increasing slice shifts of 10% (0.6 mm), 25% (1.5 mm) and 50% (3.0 mm), respectively. These images are compared to a reference image at the same position which was obtained as a single image with full radial sampling and conventional Fourier transform reconstruction. The example images reveal signal changes as a function of slice shift, which are most prominent for long-T2 components such as cerebrospinal fluid in the brain ventricles (bright signal). The effect is due to the fact that the establishment of T2/T1-like contrasts requires the proton spins to experi-ence a sufficiently large number of radiofrequency excitations. This is more easily accomplished for small slice shifts which ensure a longer period of overlapping excitations.

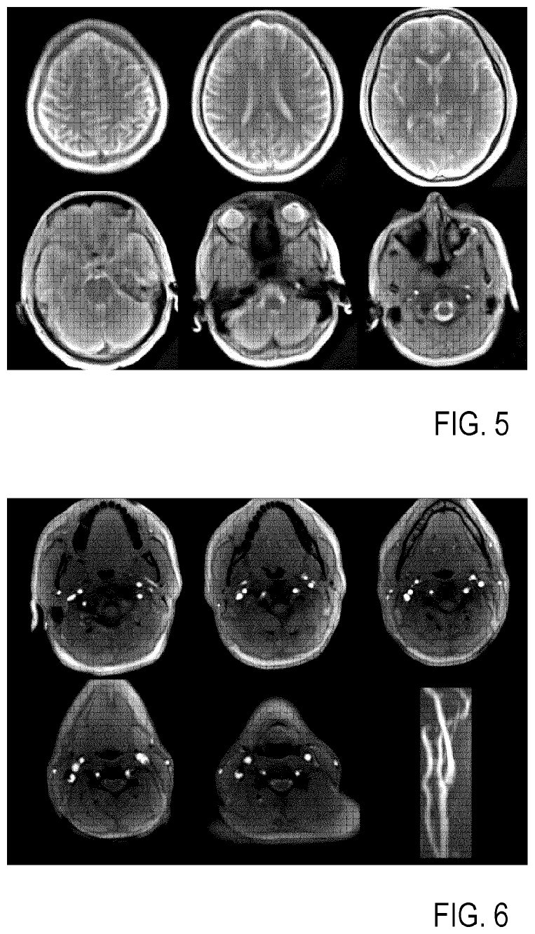

FIG. 5 depicts selected (every 15th) T2/T1-weighted images of a volume coverage scan of the brain obtained with a FLASH sequence with refocused read gradients in only 5.0 s (150 mm volume, 50.0 ms acquisition time, 1.0×1.0×6.0 mm³ resolution, slice shift 25%=1.5 mm, total number of images=100). The example demonstrates excellent image quality from (upper left) top of the brain to (lower right) bottom of the brain (e.g., negligible sensitivity to magnetic field inhomogeneity).

Another application of the invention is demonstrated in FIG. 6 which shows selected (every 20th) T1-weighted images of a volume coverage scan of the carotid arteries obtained with a sin-gle-echo FLASH sequence in only 6.4 s (128 mm volume, 40.0 ms acquisition time, 0.8×0.8×4.0 mm³ resolution, slice shift 20%=0.8 mm, total number of images=160). The lower right picture is a magnetic resonance angiogram of the carotid arteries (single side) obtained by a maximum intensity projection of the combined series of 160 cross-sectional images.

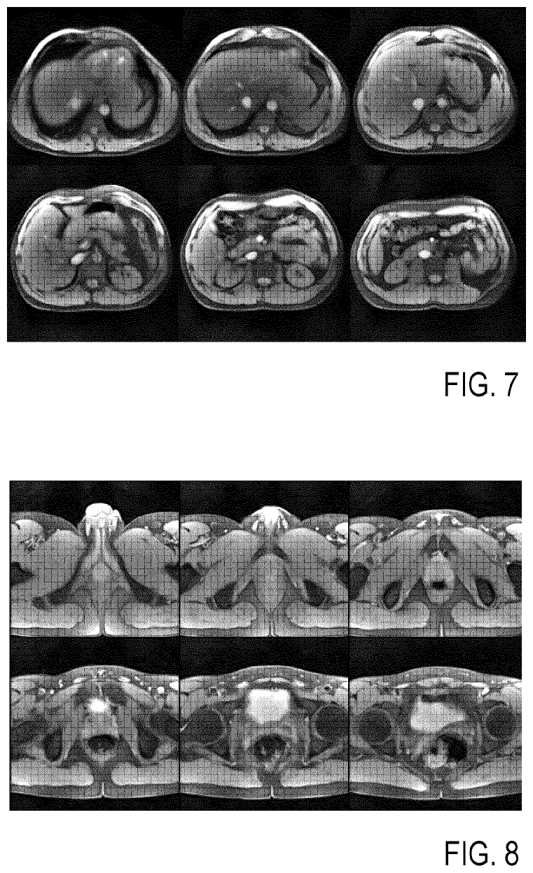

The robustness of the invention against movements is demonstrated in FIG. 7 which shows selected (every 20th) T1-weighted images of a volume coverage scan of the liver obtained with a single-echo FLASH sequence and interleaved fat suppression (each image) in only 6.0 s (180 mm volume, 50.0 ms acquisition time, 1.2×1.2×6.0 mm³ resolution, slice shift 25%=1.5 mm, total number of images=120). The scan runs from (upper left) the bottom of the beating heart to (lower right) the kidneys during free breathing. Neither cardiac pulsations nor respiratory and peristaltic movements cause any visible motion artefacts in individual images.

FIG. 8 depicts selected (every 15th) T2/T1-weighted images of a volume coverage scan of the prostate obtained with a FLASH sequence with refocused read gradients and interleaved fat suppression (every third image) in only 6.0 s (90 mm volume, 66.7 ms acquisition time, 1.0×1.0×4.0 mm³ resolution, slice shift 25%=1.0 mm, total number of images=90). The scan runs from (upper left) below the prostate to (lower right) the upper part of the bladder during free breathing. The example demonstrates insensitivity of the invention to motion and magnetic field inhomogeneity as well as the possibility to integrate and combine clinically important features such as T2/T1-contrast and fat suppression.

The application of the invention is not restricted to medical imaging, like in the above examples, but correspondingly possible for imaging other objects, like workpieces or other technical objects.

The features of the invention disclosed in the above description, the drawings and the claims can be of significance individually, in combination or sub-combination for the implementation of the invention in its different embodiments.

1. A method for creating a sequence of magnetic resonance images of an object under investigation, said sequence of magnetic resonance images representing a series of cross-sectional slices of the object, comprising the steps of:
(a) providing a series of sets of image raw data including an image content of the magnetic resonance images to be reconstructed, said image raw data being collected using at least one radiofrequency receiver coil of a magnetic resonance imaging device, wherein
each set of the image raw data includes a plurality of data samples being generated in an imaging plane with a gradient-echo sequence that spatially encodes magnetic resonance imaging signal received with the at least one radiofrequency receiver coil using a non-Cartesian k-space trajectory,
each set of the image raw data comprises a set of homogeneously distributed lines in k-space with equivalent spatial frequency content,
the lines of each set of the image raw data cross a center of k-space and cover a continuous range of spatial frequencies,
positions of the lines of each set of the image raw data differ in successive sets of image raw data, and
a number of lines of each set of image raw data is selected such that each set of the image raw data is undersampled below a sampling rate limit defined by the Nyquist—Shannon sampling theorem, and
(b) subjecting the sets of the image raw data to a regularized nonlinear inverse reconstruction process to provide the sequence of magnetic resonance images, wherein each of the magnetic resonance images is created by a simultaneous estimation of a sensitivity of the at least one receiver coil and the image content and in dependency on a difference between a current estimation of the sensitivity of the at least one receiver coil and the image content and a preceding estimation of the sensitivity of the at least one receiver coil and the image content, wherein
said cross-sectional slices of the object are contiguous cross-sectional slices, with a predetermined slice thickness,
each set of said image raw data represents one of said contiguous cross-sectional slices, and
the position of each cross-sectional slice is shifted by a slice shift in a direction perpendicular to the imaging plane in order to cover a volume of the object under investigation.

2. The method according to claim 1, wherein the method comprises a further step of
(c) combining the magnetic resonance images for creating a three-dimensional image of the object.

3. The method according to claim 1, wherein
the reconstruction process includes a filtering process suppressing image artefacts.

4. The method according to claim 3, wherein the filtering process includes at least one of
a median filter for a number of successive frames, and
a spatial filter for each frame.

5. The method according to claim 4, wherein
the filtering process includes said spatial filter for each frame, and
said spatial filter is a non-local means filter.

6. The method according to claim 1, wherein
the slice shift of successive slices in the perpendicular direction is equal to the slice thickness of the cross-sectional slices.

7. The method according to claim 1, wherein
the slice shift of successive slices in the perpendicular direction is selected in a range from 10% to 80% of the slice thickness of the cross-sectional slices.

8. The method according to claim 1, wherein the gradient-echo sequence comprises
a single-echo FLASH sequence,
a multi-echo FLASH sequence,
a FLASH sequence with refocusing read gradients,
a FLASH sequence with reversely refocusing read gradients, or
a FLASH sequence with fully balanced read and slice gradients.

9. The method according to claim 1, wherein
the number of lines of each set of the image raw data is selected such that a resulting degree of undersampling is at least a factor of 5.

10. The method according to claim 1, wherein
the number of lines of each set of the image raw data is at most 30.

11. The method according to claim 1 wherein
a duration of collecting each set of the image raw data is at most 100 ms.

12. The method according to claim 1, wherein
the lines of each set of the image raw data are selected such that the lines of successive sets of die image raw data are rotated relative to each other by a predetermined angular displacement.

13. The method according to claim 1, wherein the collection of each set of the image raw data or a selectable number of sets of the image raw data is interleaved with
a radiofrequency and gradient module for spatial pre-saturation, or
a radiofrequency and gradient module for frequency-selective saturation.

14. The method according to claim 1, wherein
steps (a) and (b) are repeated for monitoring dynamic changes of the object.

15. The method according to claim 1, wherein the sets of the image raw data are provided by at least one of
arranging the object in the magnetic resonance imaging device including the at least one receiver coil, subjecting the object to the gradient-echo sequence, and collecting the series of sets of the image raw data using the at least one receiver coil, and
receiving the sets of the image raw data by a data transmission collected from a distant magnetic resonance imaging device.

16. A magnetic resonance imaging device being configured for creating a sequence of magnetic resonance images of an object under investigation, comprising
a magnetic resonance imaging scanner including a main magnetic field device, at least one radiofrequency excitation coil, three magnetic field gradient coils and at least one radiofrequency receiver coil, and
a control device being configured for controlling the magnetic resonance imaging scanner for collecting the series of sets of image raw data and reconstructing the sequence of magnetic resonance images with the method according to claim 1.
